(19) United States
(12) Patent Application Publication
(10) Pub. No.: US 2012/0182674 A1
(43) Pub. Date: Jul. 19, 2012

(54) ELECTRONIC DEVICE HAVING DETECTOR WINDOW

(75) Inventors: TING-TING ZHAO, Shenzhen City (CN); WEI LIU, Shenzhen City (CN); MIN-LI LI, Shenzhen City (CN); BAO-GANG ZHAO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/206,815

(22) Filed: Aug. 10, 2011

(30) Foreign Application Priority Data
Jan. 19, 2011 (CN) 201110021924.6

(51) Int. Cl. H05K 7/00

(52) U.S. Cl. 361/679.01

(57) ABSTRACT

An electronic device includes a body, a detector window, and a fixing mechanism for securing the detector window to the body. The detector window is capable of being inserted into the body in a first direction, and includes at least one hook member. The fixing mechanism includes at least one latching member, at least one first limiting member and at least one second limiting member. The at least one latching member hooks the at least one hook member to limit the movement of the detector window in the first direction. The at least one latching first limiting member and the at least one second limiting member respectively are arranged opposite sides of the latching member and respectively resisting against opposite sides of the at least one hook member to cooperatively limit the movement of the detector window in a second direction perpendicular to the first direction.

### BACKGROUND

1. Technical Field

The present disclosure relates to electronic devices; and particularly to an electronic device having a detector window.

2. Description of Related Art

An electronic device, such as a DVD player, includes a body and a detector window secured to the body. The detector window includes a hook member. The body defines an opening for allowing the detector window to be inserted therein, and includes a latching member arranged adjacent to the opening. The latching member corresponds to the hook member and hooks the hook member in a first direction of the detector window being inserted into the body, such that the detector window is secured to the body. However, the hook member of the detector window is limited by the latching member only in the first direction, and the detector window may be easily detached.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout four views.

FIG. 1 is a perspective view of an electronic device in accordance with an exemplary embodiment; the electronic device includes a body and a detector window.

FIG. 2 is a partially disassembled perspective view of the electronic device of FIG. 1.

FIG. 3 is a partially assembled perspective view showing the detector window being secured to the body.

FIG. 4 is a cross-sectional view taken along line IV-IV in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

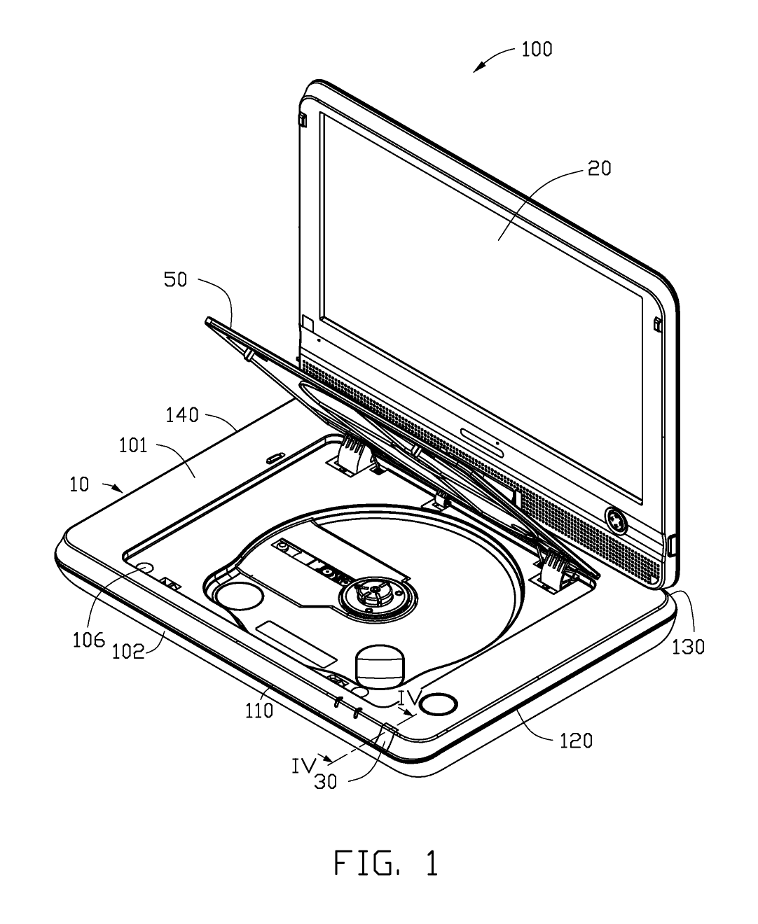

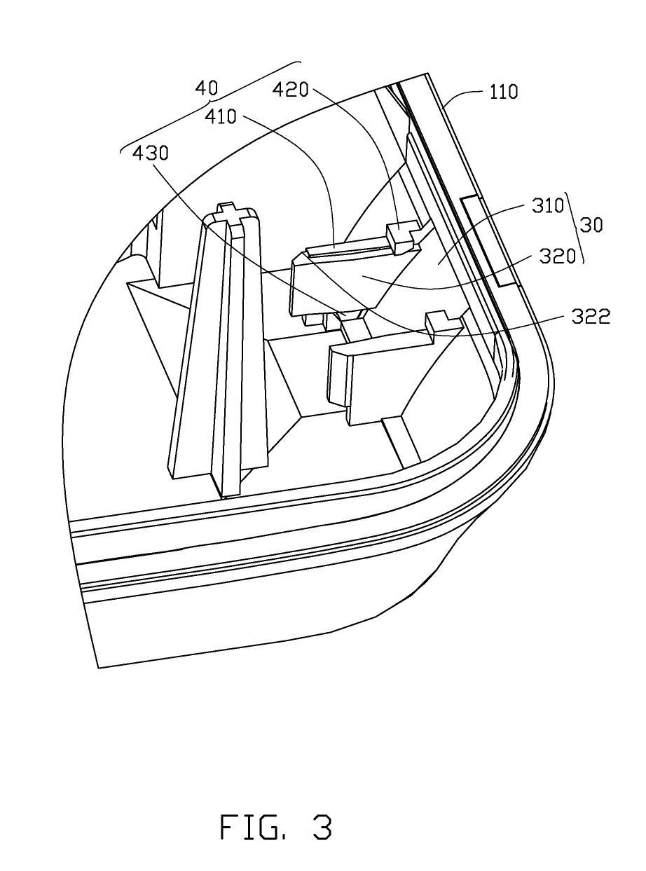

Referring to FIG. 1, a perspective view of an electronic device 100 in accordance with an embodiment is shown. The electronic device 100 includes a body 10, a cover 20 rotatably mounted to the body 10, a detector window 30 and a fixing mechanism 40 (see FIG. 3) for securing the detector window 30 to a body 10. In the embodiment, the electronic device 100 may be a portable disc player. The electronic device 100 further includes a disc cover 50. The disc cover 50 is rotatably mounted to the body 10. The disc cover 50 acts as an entrance for allowing discs (not shown) to be loaded and unloaded when the disc cover 50 is open.

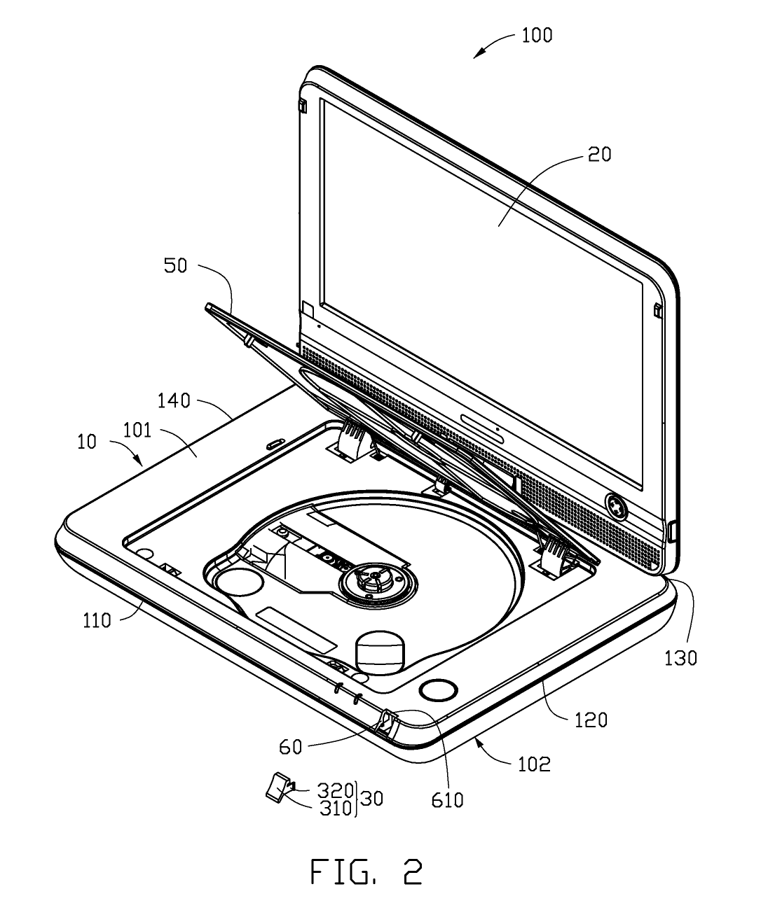

Referring also to FIG. 2, the body 10 includes a top case 101, a bottom case 102 parallel to the top case 101, and four sidewalls (hereinafter, a first sidewall 110, a second sidewall 120, a third sidewall 130 opposite to the first sidewall 110, and a fourth sidewall 140 opposite to the second sidewall 120) arranged between the top case 101 and the bottom case 102. The four sidewalls 110, 120, 130, 140 serially interconnect and cooperate with the top case 101 and the bottom case 102 to define a receiving space (not labeled) for accommodating components, such as motherboard, wireless signal receiving unit, disc drive, and other components (not shown) for operating the electronic device 100 therein. In the embodiment, the wireless signal receiving unit is accommodated in the receiving space and is arranged adjacent to an end of the first sidewall 110 connecting with the second sidewall 120. The first sidewall 110 defines an opening 60 corresponding to the wireless signal receiving unit. The receiving opening 60 communicates with the receiving space and provides an entrance to allow the detector window 30 to be inserted into the body 10. A portion of the opening 60 extends to the top case 101 to form a latching notch 610.

The detector window 30 is substantially transparent and corresponds to the wireless signal receiving unit. The wireless signal receiving unit is capable of receiving wireless signal via the detector window 30. The detector window 30 can be inserted into the opening 60 in a first direction parallel to the first sidewall 110 when being assembled. The detector window 30 includes a base 310 and two hook members 320 respectively projecting from opposite rim of the base 310. The base 310 is received in the opening 60. The contour of the base 310 matches with that of the first sidewall 110, such that the appearance of the electronic device 100 is consistent when the detector window 30 is secured to the body 10. The hook members 320 extend from the base 310 in the first direction. Ends of the hook members 320 opposite to the base 310 bend outwardly to define two hooks 322 (see FIG. 3). The hook members 320 are deformable when being pressed.

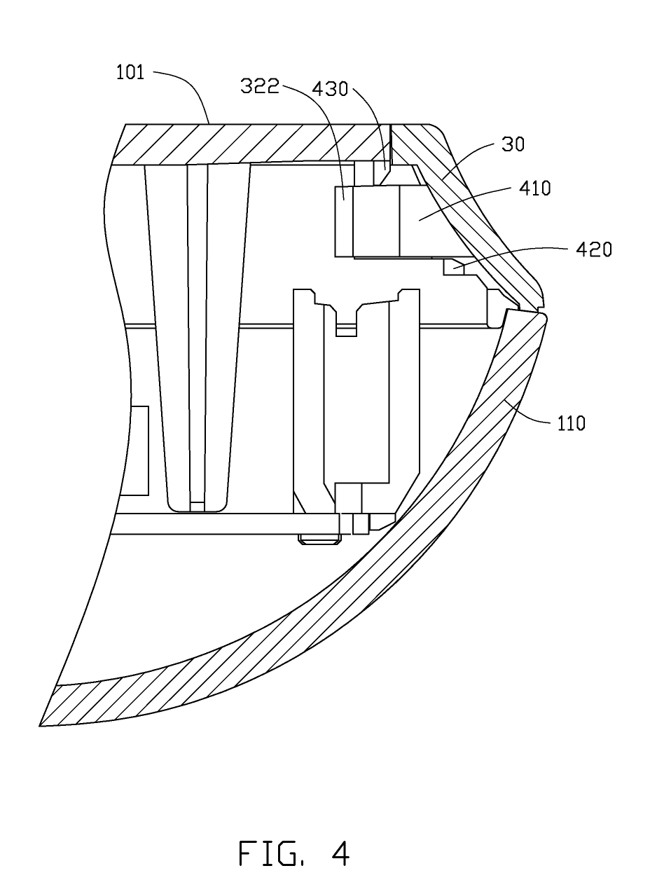

Referring to FIGS. 3 and 4, the fixing mechanism 40 includes two latching members 410, two first limiting members 420 and two second limiting members 430. The latching members 112 secure the detector window 30 to the body 10 by hooking the hooks 322. The latching members 410 project from an inner surface of the first sidewall 110 and are respectively arranged at opposite sides of the opening 50. The latching members 410 extend toward the third sidewall 130 in a direction parallel to the second and fourth sidewalls 120, 140. The two latching members 410 cooperatively define a guiding groove 412. The guiding groove 412 acts as an extension of the opening 50 and allows the hook members 320 to extend therethrough. The distance between the latching members 410 is slightly less than the distance of the hook members 320.

The first limiting members 420 project from an inner surface of the first sidewall 110. The first limiting members 420 are respectively arranged at opposite sides of the opening 50 and respectively resist against a side of the latching member 410 opposite to the top case 101. A portion of each first limiting member 420 extends into the guiding groove 412.

The second limiting members 430 project from an inner surface of the top case 101 and respectively resist against sides of the latching members 410 opposite to the first limiting members 420. A portion of each second limiting member 430 extends into the guiding groove 412 and corresponds to the portion of the corresponding first limiting member 114 extending into the guiding groove 412. One of the second liming members 430 and one of the corresponding first limiting members 420 respectively resist against opposite sides of one of the hook members 320, to limit the movement of the hook members 320 in a second direction perpendicular to the first direction.

Referring to FIGS. 3 and 4, in assembly, the hook members 320 are inserted into the body 10 via the opening 60, the hooks 322 are respectively latched to ends of the latching members 410 opposite to the first sidewall 110, and the base 310 are stopped at the latching notch 610. Thus, the detector window 30 is secured to the body 10, and the latching members 410 cooperate with the latching notch 610 to limit the movement in the first direction perpendicular to the first sidewall 110. One of the first limiting members and the corresponding second limiting member respectively resist against opposite sides of the hook members 320 to cooperatively limit the movement of the detector window 30 in the second direction perpendicular to the top plate 101. As a result, the detector window 30 is steadily secured to the body 10.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a body defining an opening;
a detector window secured to the body and capable of being inserted into the body in a first direction via the opening, the detector window comprising at least one hook member; and
a fixing mechanism arranged in the body and adapted for securing the detector window to the body, the fixing mechanism comprising at least one latching member, at least one first limiting member and at least one second limiting member, the at least one latching member hooking the at least one hook member to limit the movement of the detector window in the first direction, the at least one latching first limiting member and the at least one second limiting member respectively arranged on opposite sides of the latching member and respectively resisting against opposite sides of the at least one hook member to cooperatively limit the movement of the detector window in a second direction perpendicular to the first direction.

2. The electronic device of claim 1, wherein the detector window comprises a base, the at least one hook member projects from base and extends in a direction parallel to the first direction.

3. The electronic device of claim 2, wherein the at least one hook member is deformable.

4. The electronic device of claim 2, wherein an end of the at least one hook member opposite to the base bends to define a hook, the hook is hooked to the at least one latching member.

5. The electronic device of claim 4, wherein the body comprises a top case, a bottom case opposite to the top case, and four sidewalls arranged between the top case and the bottom case, the opening is defined at one of the sidewalls (a first sidewall).

6. The electronic device of claim 5, wherein a portion of the opening extends to one of the top case and the bottom case to form a latching notch, the latching notch is adapted to stop the base when the detector window is secured to the body.

7. The electronic device of claim 5, wherein the at least one latching member projects from the first sidewall and is arranged adjacent to a side of the opening.

8. The electronic device of claim 4, wherein the first direction is perpendicular to the first sidewall.

9. The electronic device of claim 4, wherein the second direction is perpendicular to the top base and the bottom base.
